(19) United States
(12) Patent Application Publication
(10) Pub. No.: US 2015/0014678 A1
(43) Pub. Date: Jan. 15, 2015

(54) SEMICONDUCTOR DEVICE, METHOD OF MANUFACTURING THE SAME AND SYSTEM FOR MANUFACTURING THE SAME

(71) Applicants: Industry-Academic Cooperation Foundation, Yonsei University, Seoul (KR); Samsung Display Co., Ltd., Yongin-City (KR)

(72) Inventors: Ji-Won Han, Yongin-City (KR); Tae-Woong Kim, Yongin-City (KR); Seong-Il Im, Seoul (KR); Young-Tack Lee, Seoul (KR); Pyo-Jin Jeon, Incheon-City (KR)

(73) Assignees: Industry-Academic Cooperation Foundation, Yonsei University, Seoul (KR); Samsung Display Co., Ltd., Yongin-City (KR)

(21) Appl. No.: 14/107,423

(22) Filed: Dec. 16, 2013

(30) Foreign Application Priority Data
Jul. 12, 2013 (KR) 10-2013-0082442

(51) Int. Cl. H01L 21/02; H01L 27/12; H01L 29/786

(52) U.S. Cl. CPC H01L 21/02664; H01L 29/7869; H01L 21/02565; H01L 27/1203
USPC 257/43; 438/104

(57) ABSTRACT

A method of manufacturing a semiconductor device, the method includes: providing a gate electrode on a substrate; providing a first interlayer insulating layer to cover the gate electrode on the substrate; providing an oxide semiconductor layer corresponding to the gate electrode on the first interlayer insulating layer; providing a source electrode and a drain electrode, which are in contact with the oxide semiconductor layer, on the first interlayer insulating layer; and heat-treating the oxide semiconductor layer using Joule heat generated therein from a flow of a drain current by applying a voltage to the source electrode or the drain electrode.

This application claims priority to Korean Patent Application No. 10-2013-0082442, filed on Jul. 12, 2013, and all the benefits accruing therefrom under 35 U.S.C. §119, the content of which in its entirety is herein incorporated by reference.

### BACKGROUND

1. Field

Exemplary embodiments of the invention relate to a semiconductor device, a method of manufacturing the semiconductor device and a system for manufacturing the semiconductor device, and more particularly, to a semiconductor device including a heat treated oxide semiconductor layer, a method of manufacturing the semiconductor device including a heat treating process of the oxide semiconductor layer and a system for manufacturing the semiconductor device.

2. Description of the Related Art

When forming a device, such as an integrated circuit, in a semiconductor device, a heat treatment, e.g., a heat treatment for impurity doping, a heat treatment for crystallization and recrystallization of a semiconductor, a heat treatment for recovering crystalline defects of a semiconductor, a heat treatment for removing impurities, a heat treatment for controlling a threshold voltage, a heat treatment for modifying a transistor, or the like, may be performed.

Heat treating methods of a semiconductor layer may include a furnace method and a rapid thermal annealing (“RTA”) method. The furnace method may allow a batch processing of about 200 to about 300 wafers and processing conditions to be maintained over a long period of time even when repeatedly replacing the wafers as a thermal equilibrium state is maintained in the whole chamber. The RTA method is a single wafer treating method. Thus, treating yield may be very low, however circulating time for the treatment may be fast, and various variables of a heat treating environment may be easily controlled. In addition, rapid heating may be possible using a halogen lamp, and the RTA method may be used in a process, in which a treatment period is short.

In such heat treating methods for the semiconductor layer are typically performed for a large area by a wafer unit, and typically uses a separate heat treating apparatus.

### SUMMARY

One or more exemplary embodiments of the invention include a method of manufacturing a semiconductor device in which a heat treating process is conducted using an electrical joule heating method, a system for manufacturing the semiconductor device, and a semiconductor device manufactured by the method.

Additional features will be set forth in part in the description which follows and, in part, will be apparent from the description, or may be learned by practice of the presented embodiments.

According to one or more exemplary embodiments of the invention, a method of manufacturing a semiconductor device includes providing a gate electrode on a substrate, providing a first interlayer insulating layer to cover the gate electrode on the substrate, providing an oxide semiconductor layer in a region corresponding to the gate electrode on the first interlayer insulating layer, providing a source electrode and a drain electrode, which are in contact with the oxide semiconductor layer, on the first interlayer insulating layer, and heat-treating the oxide semiconductor layer using Joule heat generated therein from a flow of a drain current by applying a voltage to the source electrode or the drain electrode.

In an exemplary embodiment, when the heat-treating the oxide semiconductor layer is performed, a portion of the oxide semiconductor layer may be exposed.

In an exemplary embodiment, the method of manufacturing a semiconductor device may further include controlling an atmosphere, to which the oxide semiconductor layer is exposed.

In an exemplary embodiment, the controlled atmosphere may be a vacuum atmosphere, an air atmosphere, an oxygen atmosphere, or a nitrogen atmosphere.

In an exemplary embodiment, the method of manufacturing a semiconductor device may further include providing a plurality of transistors on the substrate, wherein where each of the transistors includes the gate electrode, the oxide semiconductor layer, the source electrode and the drain electrode, and the heat-treating the oxide semiconductor layer includes heat-treating the oxide semiconductor layer of each transistor in a portion of the transistors using the Joule heat generated therein from the flow of the drain current by applying the voltage to the source electrode or the drain electrode of the each transistor in the portion of the transistors.

In an exemplary embodiment, the oxide semiconductor layer may be dehydrated or dehydrogenated by the heat-treating.

In an exemplary embodiment, the semiconductor device may be modified from a depletion type semiconductor device into an enhancement type semiconductor device by the heat-treating.

In an exemplary embodiment, the method of manufacturing the semiconductor device may further include providing a second interlayer insulating layer on the first interlayer insulating layer to cover the heat treated oxide semiconductor layer, the source electrode and the drain electrode.

In an exemplary embodiment, the heat treating may include controlling the voltage applied to the source electrode or the drain electrode, and a temperature of the heat treating may be controlled by the controlling the voltage.

In an exemplary embodiment, the heat treating may include applying a first voltage to the source electrode or the drain electrode and applying a second voltage to the gate electrode

According to one or more embodiments of the invention, a semiconductor device includes: a substrate; a gate electrode disposed on the substrate; a first interlayer insulating layer disposed on the substrate and which covers the gate electrode; an oxide semiconductor layer disposed on the first interlayer insulating layer in a region corresponding to the gate electrode, and a source electrode disposed on the first interlayer insulating layer and in contact with the oxide semiconductor layer; and a drain electrode disposed on the first interlayer insulating layer and in contact with the oxide semiconductor layer, where Joule heat is generated in the oxide semiconductor layer when a drain current flows therein based on a voltage applied to the source electrode or the drain electrode.

In an exemplary embodiment, the heat-treated oxide semiconductor layer may be dehydrated or dehydrogenated.

In an exemplary embodiment, the semiconductor device may be an enhancement type.

In an exemplary embodiment, the semiconductor device may further include a plurality of transistors disposed on the substrate, where each of the transistors may include the gate electrode, the oxide semiconductor layer, the source electrode and the drain electrode, a portion of the transistors may be enhancement type transistors, and another portion of the transistors may be depletion type transistors.

In an exemplary embodiment, the semiconductor device may further include a second interlayer insulating layer disposed on the first interlayer insulating layer and which covers the heat treated oxide semiconductor layer, the source electrode and the drain electrode.

According to one or more embodiments of the invention, a system for manufacturing a semiconductor device includes an atmosphere controlling device which controls an atmosphere, to which the semiconductor device is exposed, where the semiconductor device including: a substrate; a gate electrode disposed on the substrate; a first interlayer insulating layer disposed on the substrate and which covers the gate electrode; an oxide semiconductor layer disposed on the first interlayer insulating layer; a source electrode disposed on the first interlayer insulating layer and in contact with the oxide semiconductor layer; and a drain electrode disposed on the first interlayer insulating layer and in contact with the oxide semiconductor layer, where the oxide semiconductor layer exposed to the atmosphere is heat-treated using Joule heat generated therein from a flow of a drain current by applying a voltage to the source electrode or the drain electrode.

In an exemplary embodiment, the atmosphere controlling device may control the atmosphere into vacuum, an air atmosphere, an oxygen atmosphere or a nitrogen atmosphere.

In an exemplary embodiment, the system may further include a voltage controlling device which controls the applied voltage to the source electrode or the drain electrode to control a temperature of the heat-treating.

According to exemplary embodiments of the invention, a semiconductor layer is heat treated using Joule heat generated therein by a current flow. In such an embodiment, a self-heating and a selective heat treatment are effectively and efficiently performed by a transistor unit without using a separate heating apparatus, and the conditions of the heat treatment may be easily controlled.

### BRIEF DESCRIPTION OF THE DRAWINGS

The above and other features will become apparent by describing in detail exemplary embodiments thereof with reference to the attached drawings, in which:

FIG. 1 is a schematic diagram illustrating an exemplary embodiment of a system for manufacturing a semiconductor device in accordance with the invention;

FIGS. 2 to 8 are cross-sectional views schematically illustrating an exemplary embodiment of a manufacturing process of a semiconductor device in accordance with the invention;

FIG. 9 is a block diagram illustrating an exemplary embodiment of a semiconductor device in accordance with the invention;

FIG. 10 is a graph of drain current of a transistor (ampere: A) versus heating time (second: sec) in an experimental example;

FIG. 11 is a graph of drain current (A) versus gate voltage (volt: V) in a transistor, illustrating electrical properties of the transistor before and after an exemplary embodiment of a heat treatment in accordance with the invention;

FIG. 12 is a graph of drain current (A) versus gate voltage (V) in a transistor, illustrating electrical properties of transistors on a same substrate after a selective heat treating in accordance with the invention; and

FIG. 13 is a graph of drain current (A) versus gate voltage (V) in a transistor illustrating electrical properties of heat treated transistors, which are heated by a furnace method.

### DETAILED DESCRIPTION

The invention will be described more fully hereinafter with reference to the accompanying drawings, in which exemplary embodiments of the invention are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on,” “connected to” or “coupled to” another element or layer, the element or layer can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims set forth herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the invention will be described in further detail with reference to the accompanying drawings.

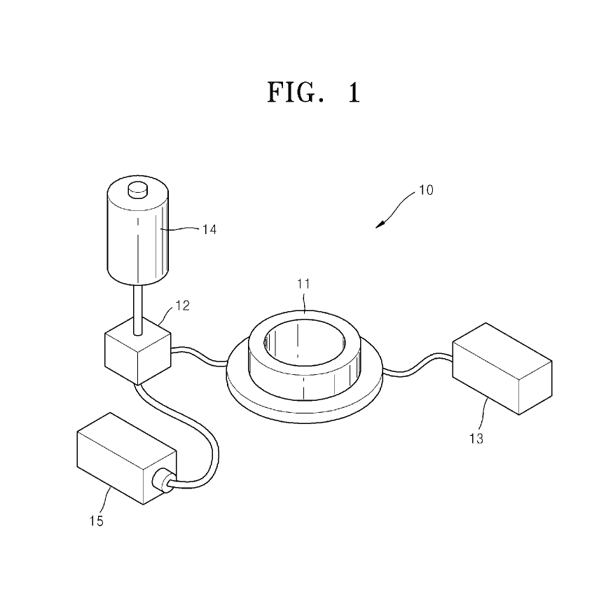

FIG. 1 is a schematic diagram illustrating an exemplary embodiment of a system for manufacturing a semiconductor device in accordance with the invention. Referring to FIG. 1, a system 10 for manufacturing a semiconductor device may include a chamber 11, an atmosphere controlling device 12, a voltage controlling device 13, a gas supplier 14 and a vacuum pump 15.

In such an embodiment, a semiconductor device may be disposed, e.g., mounted, in the chamber 11, and an environment for heat-treating the semiconductor device may be established in the chamber 11. The semiconductor device mounted in the chamber 11 may be electrically connected to an electric power source located in the chamber 11 or on an outside of the chamber 11. Referring to FIG. 1, in such an embodiment, the semiconductor device mounted in the chamber 11 may be electrically connected to the voltage controlling device 13.

The atmosphere controlling device 12 may control the atmosphere, to which the semiconductor device is exposed during the heat-treating of the semiconductor device. In one exemplary embodiment, for example, the atmosphere controlling device 12 may control the atmosphere, to which the oxide semiconductor layer of the semiconductor device is exposed.

In one exemplary embodiment, for example, the atmosphere controlling device 12 may control the vacuum pump 15 to establish a vacuum atmosphere in the chamber 11, and may control the gas supplier 14 to establish an air atmosphere or an oxygen atmosphere in the chamber 11. The method of controlling the atmosphere in the chamber 11 by the atmosphere controlling device 12 may not be limited thereto, and various atmospheres may be established in the chamber 11 based on the purpose of the heat treatment of the semiconductor device.

The gas supplier 14 may supply various gases such as hydrogen, nitrogen, oxygen, and the like or a mixture thereof, for example. The vacuum pump 11 may aspirate the gas in the chamber 11 to establish a near vacuum atmosphere in the chamber 11.

The voltage controlling device 13 may be electrically connected to the semiconductor device mounted on the chamber 11 or in the chamber 11 to apply a voltage to the semiconductor device. In one exemplary embodiment, for example, the voltage controlling device 13 may control the voltage applied to a source electrode and a drain electrode of a transistor included in the semiconductor device. A detailed description of the voltage controlling device 13 will be described later in greater detail.

In such an embodiment, the atmosphere controlling device 12, the gas supplier 14 and the vacuum pump 15 are devices that control the atmosphere in the chamber 11. Accordingly, in an alternative exemplary embodiment, where the heat treatment of the semiconductor device is performed in an air atmosphere the atmosphere controlling device 12, the gas supplier 14 and the vacuum pump 15 may be omitted. In such an embodiment, where the heat treatment of the semiconductor device is conducted in an air atmosphere, the semiconductor device may be directly connected to the voltage controlling device 13, and the chamber 11 may be omitted.

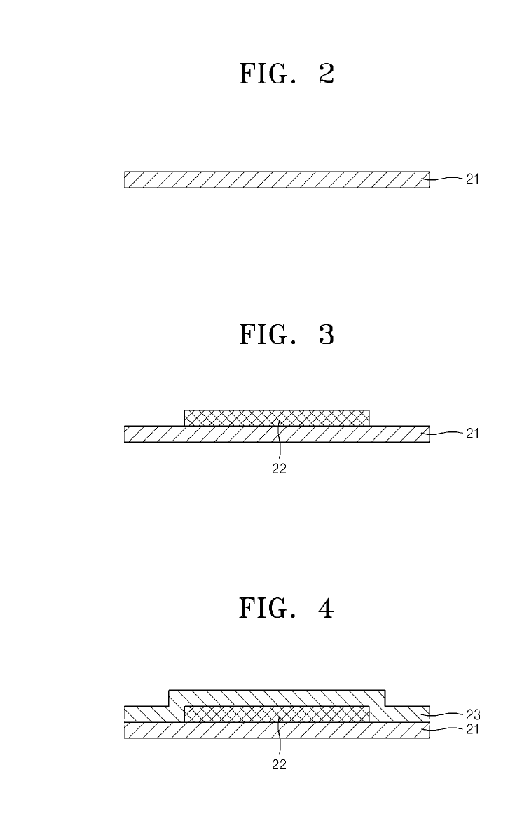

FIGS. 2 to 8 are cross-sectional views schematically illustrating an exemplary embodiment of a manufacturing process of a semiconductor device in accordance with the invention. An exemplary embodiment of the manufacturing process of the semiconductor device will be described referring to FIGS. 2 to 8.

First, a substrate 21 is provided as illustrated in FIG. 2. The substrate 21 may include a transparent glass material including SiO₂ as a main component. However, the material of the substrate 21 is not limited thereto, and substrates may include various materials such as an opaque material, a plastic material or a metal material in an alternative exemplary embodiment.

On a surface of the substrate 21, an auxiliary layer (not illustrated), such as a barrier layer, a blocking layer and/or a buffer layer, may be provided to effectively prevent the diffusion of impurity ions, to effectively prevent the penetration of humidity or air, and to effectively planarize the surface of the substrate 21. The auxiliary layer (not illustrated) may be provided using SiO₂ and/or SiNₓ using various deposition methods such as a plasma enhanced chemical vapor deposition (“PECVD”) method, an atmospheric pressure chemical vapor deposition (“APCVD”) method, a low pressure chemical vapor deposition (“LPCVD”) method, or the like.

Referring to FIG. 3, a conductive layer may be provided, e.g., deposited, on the substrate 21 and patterned to form a gate electrode 22. In an exemplary embodiment, the gate electrode 22 may include Ag, Mg, Al, Pt, Pd, Au, Ni, Nd, Ir, Cr, Li, Ca, Mo, Ti, W, MoW, Cu, or a combination thereof. However, the materials of the gate electrode 22 are not limited thereto, and the gate electrode 22 may include any conductive materials including a metal in an alternative exemplary embodiment.

Referring to FIG. 4, a first interlayer insulating layer 23 may be provided, e.g., formed, on the structure in FIG. 3. The first interlayer insulating layer 23 may be provided, formed, on the substrate 21 to cover the gate electrode 22.

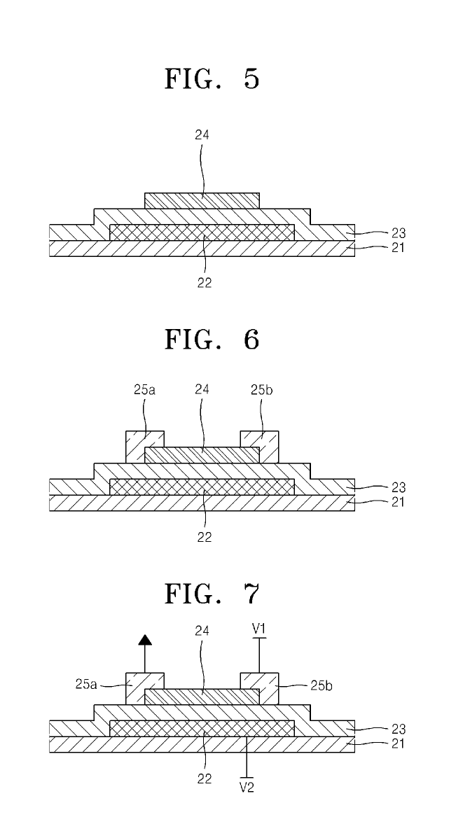

Referring to FIG. 5, an oxide semiconductor layer 24 may be provided on the structure in FIG. 4. In such an embodiment, the oxide semiconductor layer 24 may be provided in a region corresponding to the gate electrode 22 on the first interlayer insulating layer 23. In an exemplary embodiment, as shown in FIG. 5, the oxide semiconductor layer 24 may be patterned to be completely included in the patterned region of the gate electrode 22. The oxide semiconductor layer 24 may be provided to be substantially completely aligned with the gate electrode 22.

In an exemplary embodiment, the oxide semiconductor layer 24 may include an oxide of a metal element in Groups 12, 13 and 14 such as zinc (Zn), indium (In), gallium (Ga), tin (Sn), cadmium (Cd), germanium (Ge) and hafnium (Hf), or a combination thereof, for example, but not being limited thereto.

Referring to FIG. 6, a conductive layer may be provided, e.g., deposited, on the structure shown in FIG. 5 and patterned to form a source electrode 25a and a drain electrode 25b. In such an embodiment, the source electrode 25a and the drain electrode 25b, which are in contact with a portion of the oxide semiconductor layer 24, may be provided on the first interlayer insulating layer 23.

Referring to FIG. 6, a portion of the upper surface of the oxide semiconductor layer 24 may be covered by the source electrode 25a and the drain electrode 25b, and at least a portion of the oxide semiconductor layer 24 may be exposed by the source electrode 25a and the drain electrode 25b. In such an embodiment, as shown in FIG. 6, an upper surface of the oxide semiconductor layer 24 may be substantially completely exposed. The exposed region of the oxide semiconductor layer 24 may be exposed to an exterior environment (e.g., vacuum, air, peroxide environment, etc.) during heat-treating.

In an exemplary embodiment, a metal layer may be provide, e.g., stacked, on the structure in FIG. 5 and selectively etched to form the source electrode 25a and the drain electrode 25b. In such an embodiment, the etching process may be conducted by various methods such as a wet etching and a dry etching. In an exemplary embodiment, the metal layer may include Ag, Mg, Al, Pt, Pd, Au, Ni, Nd, Ir, Cr, Li, Ca, Mo, Ti, W, MoW, Cu or a combination thereof. However, the materials of the source electrode 25a and the drain electrode 25b are not limited thereto, and the source electrode 25a and the drain electrode 25b may include any conductive materials including a metal in an alternative exemplary embodiment.

The method of providing the source electrode 25a and the drain electrode 25b may not be limited to the above-described method. In one alternative exemplary embodiment, for example, the source electrode 25a and the drain electrode 25b may be patterned using a mask process including a lift-off process.

In an exemplary embodiment, where the source electrode 25a and the drain electrode 25b are provided by the lift-off process, a masking layer is provided to cover a portion where a thin film is not to be provided, the thin film is deposited on the masking layer, and the masking layer is then removed. In such an embodiment, the thin film provided on the masking layer may be removed, and the thin film provided on a portion of the substrate that is exposed by the masking layer may remain. That is, the masking layer having a reverse pattern with respect to a predetermined pattern (e.g., a pattern corresponding to a pattern of the source electrode 25a and the drain electrode 25b) is previously provided, the thin film is formed thereon, and then the masking layer is removed. Then, the thin film covering the masking layer may be removed, such that the thin film having the predetermined pattern is provided.

Referring to FIG. 7, the oxide semiconductor layer 24 with the structure shown in in FIG. 6 may be heat treated. In such an embodiment, the heat treatment may be conducted for various purposes.

In an exemplary embodiment, the heat treatment may be performed for changing the properties of the oxide semiconductor layer 24. In one exemplary embodiment, for example, the heat treatment may be performed for changing a depletion type transistor into an enhancement type transistor.

The depletion type transistor is a transistor, in which a channel is formed without an application of a voltage, and a current may be shut off when an inverse voltage is applied. The enhancement type transistor is a transistor, in which the channel is not formed, and a current may flow when a forward voltage is applied. That is, the threshold voltage for forming the channel may be less than about zero (0) volt (V) in the depletion type transistor, and the threshold voltage for forming the channel may be greater than about zero (0) V in the enhancement type transistor. Such characteristics of a transistor may be changed by the heat treatment. The threshold voltage of the transistor may be modified by the heat treatment.

In an exemplary embodiment, the heat treatment may be performed for the dehydration or dehydrogenation of the oxide semiconductor layer 24. Generally, when the hydrogen content in the oxide semiconductor layer 24 is high, the concentration of carriers may be increased, and the threshold voltage of the oxide transistor may move toward a negative direction, e.g., may be decreased. When the dehydration or the dehydrogenation is conducted, the hydrogen content in the oxide semiconductor layer 24 may be decreased, and the threshold voltage of the oxide transistor may be applied toward a positive direction, e.g., may be increased. Thus, the depletion type transistor may be changed into the enhancement type transistor when the heat treatment is performed for the oxide semiconductor layer thereof.

The purpose of the heat treatment is not limited thereto, and an exemplary embodiment of the heat treating method may be used for various purposes. In an exemplary embodiment, a high temperature environment may be provided for conducting the heat treatment of the oxide semiconductor layer 24.

In an exemplary embodiment of the invention, a first voltage V1 may be applied to the source electrode 25a or the drain electrode 25b. A current may flow through the oxide semiconductor layer 24 due to the voltage difference between the source electrode 25a and the drain electrode 25b, and the oxide semiconductor layer 24 may be heat treated by the Joule heat generated from the current flow therethrough.

Referring to FIG. 7, in one exemplary embodiment, for example, the source electrode 25a may be connected to a ground, and the first voltage V1 may be applied to the drain electrode 25b. When a voltage difference is generated between the source electrode 25a and the drain electrode 25b through the application of the first voltage V1, a drain current may flow through the oxide semiconductor layer 24. In such an embodiment, Joule heat may be generated from the flowing of the current through the oxide semiconductor layer 24. In such an embodiment, a heat treating temperature of the oxide semiconductor layer 24 may be equal to or greater than about 1,000° C. by the Joule heat, and a self-heating of the oxide semiconductor layer 24 is thereby performed.

In an example embodiment of the invention, a second voltage V2 may be applied to the gate electrode 22. In such an embodiment, the second voltage V2 applied to the gate electrode may increase the amount of current that flows through the oxide semiconductor layer 24.

The voltage controlling device 13 in FIG. 1 may control the values of the first voltage V1 and the second voltage V2, and may thereby control the drain current. In such an embodiment, a generation of the Joule heat and a heat treating temperature may be controlled by controlling the drain current. In one exemplary embodiment, for example, the voltage control device 13 may increase the first voltage V1 or the second voltage V2 to increase the heat treating temperature. In such an embodiment, the voltage controlling device 13 may lower the first voltage V1 or the second voltage V2 to decrease the heat treating temperature.

In an exemplary embodiment of the invention, the heat treatment of the oxide semiconductor layer 24 may be conducted to the structure where at least a portion of the oxide semiconductor layer 24 is exposed, as shown in FIG. 6. In one exemplary embodiment, for example, the heat treatment may be conducted to a structure where the upper surface of the oxide semiconductor layer 24 is completely exposed.

As described above, the atmosphere controlling device 12 in FIG. 1 may control the atmosphere which the oxide semiconductor layer 24 is exposed to. In one exemplary embodiment, for example, the atmosphere controlling device 12 may control a vacuum atmosphere, an air atmosphere, an oxygen atmosphere, an air atmosphere including a certain component ratio, or the like, which the oxide semiconductor layer 24 is exposed to. In such an embodiment, the atmosphere controlling device 12 may use a vacuum pump 15 or may use a gas supplier 14 for providing various kinds of gases to control the atmosphere which the oxide semiconductor layer 24 is exposed to. The atmosphere controlling device 12 may be supplied with hydrogen, nitrogen, air, or the like from the gas supplier 14. The component ratio of each gas may be controlled by the atmosphere controlling device 12.

The oxide semiconductor layer 24 exposed to the atmosphere controlled by the atmosphere controlling device 12 may be heat treated. In one exemplary embodiment, for example, the oxygen component in the oxide semiconductor layer 24 heat treated in the air atmosphere or the oxygen atmosphere may be increased to form an enhancement type transistor. In one exemplary embodiment, for example, the oxide semiconductor layer 24 when heated in the nitrogen atmosphere or the vacuum may form the enhancement type transistor due to the hydrogen doping effect.

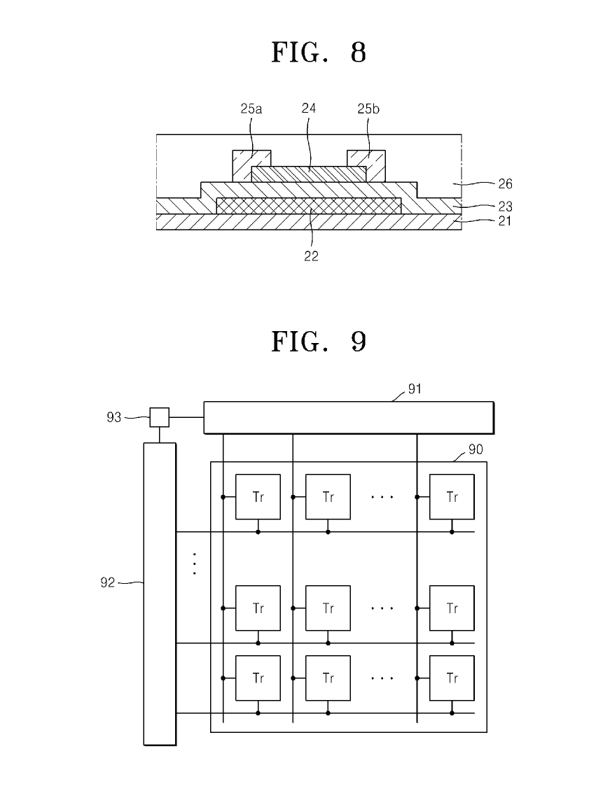

Referring to FIG. 8, a second interlayer insulating layer 26 may be provided, e.g., formed, on the heat treated structure in FIG. 7. The second interlayer insulating layer 26 may be formed on the first interlayer insulating layer 23 to cover the heat treated oxide semiconductor layer 24, the source electrode 25a and the drain electrode 25b. The second interlayer insulating layer 26 may be patterned to form holes (not illustrated) that expose a portion of the source electrode 25a or the drain electrode 25b therein.

The second interlayer insulating layer 26 may be formed by a spin coating, or the like, using an organic insulating material including polyimide, polyamide, an acryl resin, benzocyclobutene, a phenol resin or a combination thereof. The second interlayer insulating layer 26 may be formed using an inorganic insulating material including SiO₂, SiNₓ, Al₂O₃, CuOₓ, Tb₄O₇, Y₂O₃, Nb₂O₅, Pr₂O₃, or a combination thereof. In an exemplary embodiment, the second insulating layer 26 may be formed to have a multi-layered structure by alternately providing an organic insulating material layer and an inorganic insulating material layer on one another. In an alternative exemplary embodiment, a process for providing the second interlayer insulating layer 26 may be omitted.

In an exemplary embodiment, the second interlayer insulating layer 26 may be provided to have a predetermined thickness, for example, a thickness greater than a thickness of the first interlayer insulating layer 23, and the second interlayer insulating layer 26 may function as a planarization layer for planarizing the upper surface of the semiconductor device or a passivation layer for passivating the source and drain electrodes 25a and 25b.

FIG. 9 is a block diagram illustrating an exemplary embodiment of a semiconductor device in accordance with the invention. Referring to FIG. 9, a semiconductor device may include a plurality of transistors Tr disposed on a substrate 90. In such an embodiment, each transistor Tr may include a gate electrode, an oxide semiconductor layer, a source electrode and a drain electrode, on a substrate 90. In one exemplary embodiment, for example, the transistor Tr may be a field effect transistor (“FET”), but not being limited thereto.

Referring to FIG. 9, the transistors Tr of the semiconductor device may each receive a signal from a data signal supplier 91 and a switching signal supplier 92. A signal supplier 93 may control the signal supply and signal timing of the data signal supplier 91 and the switching signal supplier 92.

In such an embodiment, a first voltage V1 may be applied to the drain electrode of each transistor Tr by the driving of the data signal supplier 91 and the switching signal supplier 92. In an exemplary embodiment, the semiconductor device may further include a gate signal supplier (not shown). The gate signal supplier may apply a second voltage V2 to the gate electrode of the transistor Tr while applying the first voltage V1 to the transistor Tr to increase the amount of a drain current that flows to the transistor.

Referring to FIG. 9, the first voltage V1 may be selectively supplied to the transistors Tr included in the semiconductor device based on the control of the data signal supplier 91 and the switching signal supplier 92. In such an embodiment, the oxide semiconductor layers of a portion of the transistors Tr may be heat-treated by supplying the first voltage V1 only to the source electrode or the drain electrode thereof.

The described above, selective heat treatment of the transistor may be performed by an exemplary embodiment of a heat treating process in accordance with the invention, by selectively supplying a voltage to the electrodes of the transistors.

Through the selective heat treatment, the semiconductor device may include both heat treated transistors and heat un-treated transistors at the same time on the substrate 90. In an exemplary embodiment, where the heat treatment is conducted for the modification of the transistor, a semiconductor device may include a depletion type transistor and an enhancement type transistor on the substrate 90. In such an embodiment, a portion of the transistors may be the enhancement type, and another portion of the transistors may be the depletion type among the transistors included in the semiconductor device. In such an embodiment, a logical circuit, such as an inverter, or a memory device, such as a static random-access memory (“SRAM”), may be efficiently and effectively provided on the substrate 90 by using transistors of different types.

The data signal supplier 91 and a gate signal supplier (not illustrated) may be electrically connected to the voltage controlling device 13 in FIG. 1, and the heat treating process of the transistor Tr may be controlled by controlling the magnitude of the first voltage V1 and the second voltage V2.

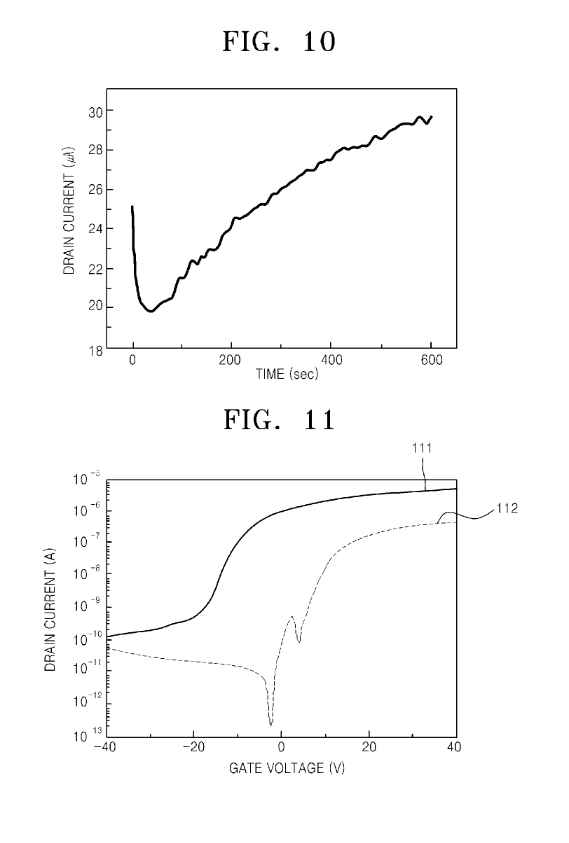

FIG. 10 is a graph of drain current of a transistor (ampere: A) versus heating time (second: sec). In FIG. 10, the values of the drain current flowing through the oxide semiconductor layer versus the heat treating time is shown, which is measured in an experiment where a first voltage of about 60 V is applied to the drain electrode. In the experiment, a semiconductor layer including a nanowire having a diameter of about 100 nanometers (nm) and an electric conductivity of about 266.4 siemens per meter (S/m) was used.

Referring to FIG. 10, as the heat treating process progresses, e.g., as the heating time increases, the type of the semiconductor layer is changed, and the drain current is thereby increased.

FIG. 11 is a graph of drain current (A) versus gate voltage (V) in a transistor illustrating electrical properties of the transistor before and after an exemplary embodiment of heat treatment in accordance with the invention. In FIG. 11, a first curve 111 illustrates the electrical properties of the transistor before the heat treatment, and a second curve 112 illustrates the electrical properties of the transistor after the heat treatment.

Referring to FIG. 11, the threshold voltage of the transistor before the heat treatment is in a range of about −20 V to about −15 V, as shown by the first curve 111, but is in a range of about zero (0) V to about 5 V before the heat treatment, as shown by the second curve 112. Through the heat treatment of the transistor, the threshold voltage moves to a positive direction, e.g., increased.

FIG. 12 is a graph of drain current (A) versus gate voltage (V) in a transistor illustrating electrical properties of transistors on the same substrate after an exemplary embodiment of a selective heat treatment in accordance with the invention. Particularly, FIG. 12 illustrates electrical properties of a heat-untreated transistor and a heat-treated transistor on the same substrate after conducting an exemplary embodiment of a selective heat treatment in accordance with the invention. A second curve 122 in FIG. 12 illustrates the electrical properties of the heat-treated transistor when the first voltage and the second voltage were applied by the control of the data signal supplier 91, the switching signal supplier 92 and the gate signal supplier (not illustrated) in FIG. 9. A first curve 121 in FIG. 12 illustrates the electrical properties of the heat-untreated transistor when the first voltage and the second voltage were not applied.

Referring to FIG. 12, the threshold voltage of the heat un-treated transistor is about −15 V, and the threshold voltage of the heat treated transistor is in a range of about zero (0) V to 5 V. In an exemplary embodiment, as shown in FIG. 12, the heat treated transistor may be the enhancement type transistor, and the heat un-treated transistor may be the depletion type transistor. A shown in FIG. 12, a portion of the transistors, to which the first and second voltages are applied, were heat treated, while the remaining portion of the transistors, to which the first and second voltage are not applied, were not heat treated by the selective heat treatment.

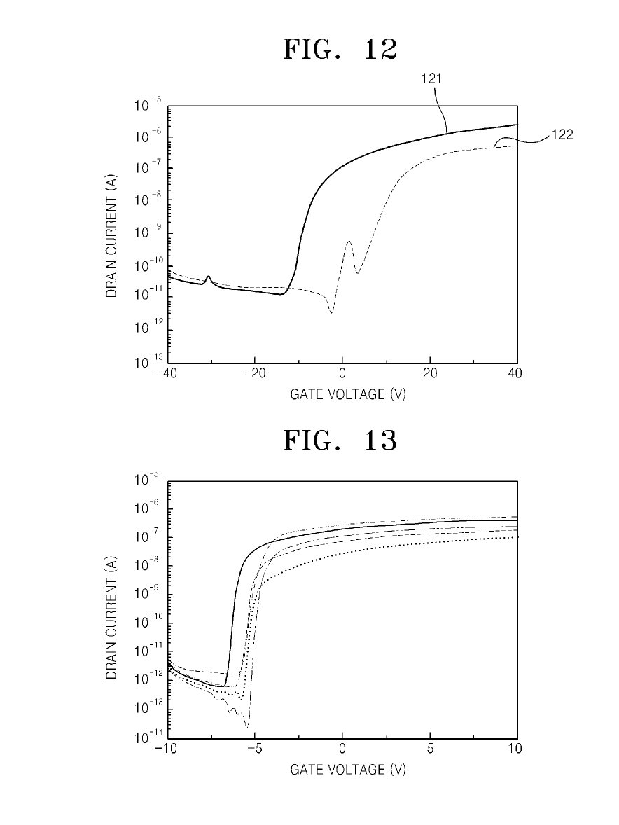

FIG. 13 is a graph of drain current (A) versus gate voltage (V) in a transistor illustrating electrical properties of transistors heat treated by a furnace method. Particularly, FIG. 13 illustrates the electrical properties of various transistors after heat treating all of the transistors included in the semiconductor device at about 600° C. for about 30 minutes by a conventional furnace system.

Referring to FIG. 13, the properties of the transistors are changed due to the heat treatment using the furnace system. However, selective heat treatment was found to be impossible when using the furnace system, and the heat treatment effect was applied to all of the transistors.

As described above, in an exemplary embodiment of the invention, the self-heating of a semiconductor device is performed without using a separate apparatus by heat-treating the semiconductor device using Joule heat generated therein by applying a voltage to the semiconductor device. In such an embodiment, a heat treatment of a portion of transistors disposed on a same substrate may be performed by selectively applying voltage to the portion of the transistors. By efficiently and effectively providing a plurality of transistors having various types on a single substrate, a complex logical circuit such as AND, OR, NOT, NOR, NAND, and the like, or a memory device such as an SRAM may be efficiently and effectively provided in the single substrate.

In a conventional heat treating method, where the semiconductor layer are heat-treated with respect to a large area by a wafer unit (e.g., a furnace method), selective heat treatment with respect to a transistor unit within the wafer may be difficult. In a conventional heat treating method, where a separate heat treating apparatus is used (e.g., a rapid thermal annealing method), energy consumption required for the heating may be large, and the control of a heat treating temperature may be difficult. In an exemplary embodiment of the invention, as described herein, the temperature of the heat treatment of the semiconductor device may be easily controlled by controlling voltage applied to the semiconductor device, when compared with a conventional heat treatment method, in which the temperature of a chamber may be wholly increased, or thermal energy generated from outside may be directly transferred.

In such an embodiment, the heat treatment may be conducted to a semiconductor layer that is exposed, and the exposed atmosphere may be controlled such that various kinds of the heat treatment may be conducted.

In an exemplary embodiment of a method of manufacturing a semiconductor device, the removal of the stacked layer while performing each mask process for manufacturing the semiconductor device may be conducted by a dry etching or a wet etching. Each of the mask processes for manufacturing the semiconductor device may be conducted by a lift-off method. However, the method for conducting the mask process may not be limited thereto.

In FIGS. 2 to 8, only a single transistor is shown to illustrate an exemplary embodiment of the method of manufacturing the semiconductor device according to the invention, for convenience of illustration and description. However, the invention is not limited thereto, and a plurality of transistors may be manufactured using an exemplary embodiment of the method of manufacturing the semiconductor device.

In an exemplary embodiment, the transistor may be a thin film transistor (“TFT”).

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the invention have been described with reference to the figures, it will be understood by those of ordinary skill in the art that various changes in form and details may be made therein without departing from the spirit and scope of the invention as defined by the following claims.

What is claimed is:

1. A method of manufacturing a semiconductor device, the method comprising:
providing a gate electrode on a substrate;
providing a first interlayer insulating layer to cover the gate electrode on the substrate;
providing an oxide semiconductor layer in a region corresponding to the gate electrode on the first interlayer insulating layer;
providing a source electrode and a drain electrode, which are in contact with the oxide semiconductor layer, on the first interlayer insulating layer; and
heat-treating the oxide semiconductor layer using Joule heat generated therein from a flow of a drain current by applying a voltage to the source electrode or the drain electrode.

2. The method of manufacturing a semiconductor device of claim 1, wherein
when the heat-treating the oxide semiconductor layer is performed, a portion of the oxide semiconductor layer is exposed.

3. The method of manufacturing a semiconductor device of claim 2, further comprising:
controlling an atmosphere, to which the oxide semiconductor layer is exposed.

4. The method of manufacturing a semiconductor device of claim 3, wherein
the controlled atmosphere is a vacuum atmosphere, an air atmosphere, an oxygen atmosphere, or a nitrogen atmosphere.

5. The method of manufacturing a semiconductor device of claim 1, further comprising:
providing a plurality of transistors on the substrate,
wherein
each of the transistors comprises the gate electrode, the oxide semiconductor layer, the source electrode and the drain electrode, and
the heat-treating the oxide semiconductor layer comprises heat-treating the oxide semiconductor layer of each transistor in a portion of the transistors using the Joule heat generated therein from the flow of the drain current by applying the voltage to the source electrode or the drain electrode of the each transistor in the portion of the transistors.

6. The method of manufacturing a semiconductor device of claim 1, wherein
the oxide semiconductor layer is dehydrated or dehydrogenated by the heat-treating.

7. The method of manufacturing a semiconductor device of claim 1, wherein
the semiconductor device is modified from a depletion type semiconductor device into an enhancement type semiconductor device by the heat-treating.

8. The method of manufacturing a semiconductor device of claim 1, further comprising:
providing a second interlayer insulating layer on the first interlayer insulating layer to cover the heat treated oxide semiconductor layer, the source electrode and the drain electrode.

9. The method of manufacturing a semiconductor device of claim 1, wherein
the heat-treating comprises controlling the voltage applied to the source electrode or the drain electrode, and
a temperature of the heat-treating is controlled by the controlling the voltage.

10. The method of manufacturing a semiconductor device of claim 1, wherein
the heat-treating comprises applying a first voltage to the source electrode or the drain electrode and applying a second voltage to the gate electrode.

11. A semiconductor device comprising:
a substrate;
a gate electrode disposed on the substrate;
a first interlayer insulating layer disposed on the substrate and which covers the gate electrode;
an oxide semiconductor layer disposed on the first interlayer insulating layer in a region corresponding to the gate electrode;
a source electrode disposed on the first interlayer insulating layer and in contact with the oxide semiconductor layer; and
a drain electrode disposed on the first interlayer insulating layer and in contact with the oxide semiconductor layer,
wherein Joule heat is generated in the oxide semiconductor layer when a drain current flows therein based on a voltage applied to the source electrode or the drain electrode.

12. The semiconductor device of claim 11, wherein the heat-treated oxide semiconductor layer is dehydrated or dehydrogenated.

13. The semiconductor device of claim 11, wherein the semiconductor device is an enhancement type semiconductor device.

14. The semiconductor device of claim 11, further comprises
a plurality of transistors disposed on the substrate,
wherein
each of the transistors comprises the gate electrode, the oxide semiconductor layer, the source electrode and the drain electrode,
a portion of the transistors are enhancement type transistors, and
another portion of the transistors are depletion type transistors.

15. The semiconductor device of claim 11, further comprising:
a second interlayer insulating layer disposed on the first interlayer insulating layer and which covers the heat treated oxide semiconductor layer, the source electrode and the drain electrode.

16. A system for manufacturing a semiconductor device, the system comprising:
an atmosphere controlling device which controls an atmosphere, to which the semiconductor device is exposed,
wherein the semiconductor device comprises:
a substrate;
a gate electrode disposed on the substrate;
a first interlayer insulating layer disposed on the substrate and which covers the gate electrode;
an oxide semiconductor layer disposed on the first interlayer insulating layer;
a source electrode disposed on the first interlayer insulating layer and in contact with the oxide semiconductor layer; and
a drain electrode disposed on the first interlayer insulating layer and in contact with the oxide semiconductor layer, and
wherein the oxide semiconductor layer exposed to the atmosphere is heat-treated using Joule heat generated therein from a flow of a drain current by applying a voltage to the source electrode or the drain electrode.

17. The system of claim 16, wherein
the atmosphere controlling device controls the atmosphere into a vacuum atmosphere, an air atmosphere, an oxygen atmosphere or a nitrogen atmosphere.

18. The system of claim 16, further comprising:
a voltage controlling device which controls the voltage applied to the source electrode or the drain electrode to control a temperature of the heat-treating.
